(19) United States
(12) Patent Application Publication
(10) Pub. No.: US 2014/0116504 A1
(43) Pub. Date: May 1, 2014

(54) COMPOUND SEMICONDUCTOR SOLAR CELL

(71) Applicant: Electronics and Telecommunications Research Institute, (US)

(72) Inventors: Yong-Duck CHUNG, Daejeon (KR); Daehyung CHO, Seoul (KR)

(73) Assignee: Electronics and Telecommunications Research Institute, Daejeon (KR)

(21) Appl. No.: 13/845,766

(22) Filed: Mar. 18, 2013

(30) Foreign Application Priority Data
Oct. 30, 2012 (KR) 10-2012-0121398

(51) Int. Cl. H01L 31/032

(52) U.S. Cl. CPC H01L 31/0322
USPC 136/256; 136/262

(57) ABSTRACT

Provided is a compound semiconductor solar cell including a back electrode disposed on a substrate, a hole-injection layer disposed on the back electrode, a light-absorbing layer disposed on the hole-injection layer, and a front transparent electrode disposed on the light-absorbing layer. The hole-injection layer may be formed of a metal oxide layer containing one or more metallic element.

### CROSS-REFERENCE TO RELATED APPLICATIONS

This U.S. non-provisional patent application claims priority under 35 U.S.C. §119 to Korean Patent Application No. 10-2012-0121398, filed on Oct. 30, 2012, in the Korean Intellectual Property Office, the entire contents of which are hereby incorporated by reference.

### BACKGROUND OF THE INVENTION

Example embodiments of the inventive concept relate to a compound semiconductor solar cell, and in particular, to a compound semiconductor solar cell with improved efficiency.

Due to a limitation of insufficient silicon raw materials caused by the growth of solar cell market, interest in thin film solar cells is increasing. A thin film solar cell, according to its material, may be classified into an amorphous or crystalline silicon thin film solar cell, a copper indium gallium selenide (CIGS) based thin film solar cell, a cadmium telluride (CdTe) thin film solar cell, a dye-sensitized solar cell, etc. A light-absorbing layer of a CGIS-based thin film solar cell is composed of I-III-VI₂ compound semiconductors (e.g., CuInSe₂, Cu(In,Ga)Se₂, Cu(Al,In)Se₂, Cu(Al,Ga)Se₂, Cu(In,Ga)(S,Se)₂, (Au,Ag,Cu)(In,Ga,Al)(S,Se)₂) represented by copper indium diselenide (CuInSe₂). The light-absorbing layer has a direct transition type energy bandgap and a high optical absorption coefficient such that a highly efficient solar cell can be manufactured in the form of a thin film having a thickness of about 1-2 μm.

It is known that the efficiency of a CGIS-based thin film solar cell is not only higher than some commercialized thin film solar cells such as amorphous silicon, CdTe and the like, but also close to a typical polycrystalline silicon solar cell. Also, the CGIS-based thin film solar cell not only can be manufactured with lower cost constituent materials than other types of solar cell materials and flexible, but has characteristics in which its performance is not deteriorated for a long period of time.

### SUMMARY

Example embodiments of the inventive concept provide a compound semiconductor solar cell with improved efficiency.

According to example embodiments of the inventive concepts, a compound semiconductor solar cell may include a back electrode disposed on a substrate, a hole-injection layer disposed on the back electrode, a light-absorbing layer disposed on the hole-injection layer, and a front transparent electrode disposed on the light-absorbing layer. The hole-injection layer may be formed of a metal oxide layer containing one or more metallic element.

In example embodiments, a difference between a valence band of the hole-injection layer and a valence band of a p-type semiconductor of the light-absorbing layer may be larger than a difference between a conduction band of the hole-injection layer and the valence band of the p-type semiconductor of the light-absorbing layer.

In example embodiments, the hole-injection layer may include at least one of a nickel oxide layer, a vanadium oxide layer, a tungsten oxide layer, or a ruthenium oxide layer.

In example embodiments, the hole-injection layer has a multi-layered structure including at least two of a nickel oxide layer, a vanadium oxide layer, a tungsten oxide layer, and a ruthenium oxide layer.

In example embodiments, the hole-injection layer has a thickness ranging from 0.001 μm to 1.0 μm.

In example embodiments, the light-absorbing layer may be formed of I-III-VI₂ compound semiconductor.

In example embodiments, the solar cell may further include a buffer layer interposed between the light-absorbing layer and the front transparent electrode.

In example embodiments, the solar cell may further include an anti-reflecting layer disposed on the front transparent electrode and a grid electrode disposed at a side of the anti-reflecting layer to be in contact with the front transparent electrode.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a compound semiconductor solar cell according to example embodiments of the inventive concept.

FIG. 2 is an energy band diagram of a back electrode of a conventional solar cell.

FIG. 3 is an energy band diagram of a back electrode of a solar cell according to example embodiments of the inventive concept.

FIG. 4 is a flow chart illustrating a method of fabricating a compound semiconductor solar cell, according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

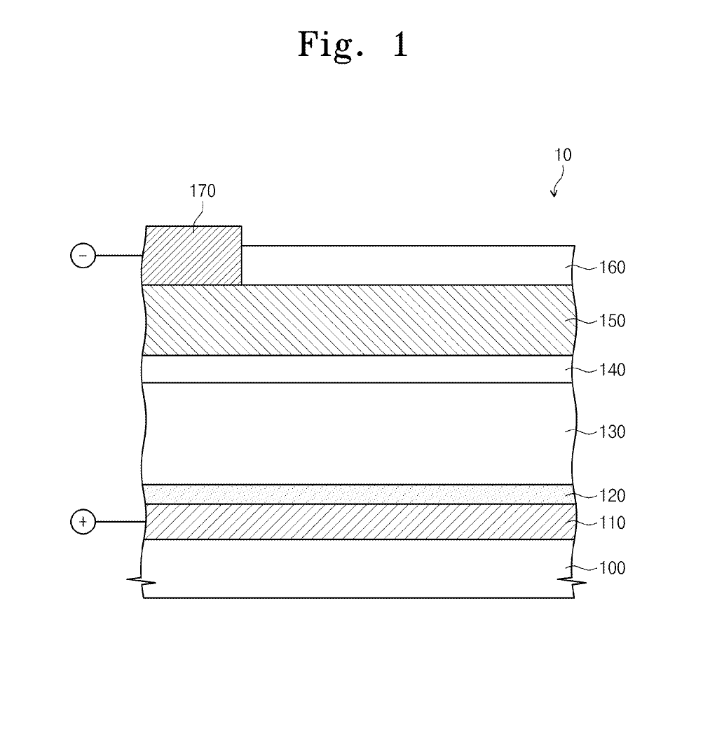

FIG. 1 is a sectional view illustrating a compound semiconductor solar cell according to example embodiments of the inventive concept.

Referring to FIG. 1, a compound semiconductor solar cell 10 may include a substrate 100 and a back electrode 110, a hole-injection layer 120, a light-absorbing layer 130, a buffer layer 140, a front transparent electrode 150, an anti-reflecting layer 160, and a grid electrode 170 that are sequentially provided on the substrate 100.

The substrate 100 may be a soda lime glass substrate. The soda lime glass substrate may contain sodium. The sodium (Na) in the soda lime glass substrate may be diffused into the light-absorbing layer 130 of the compound semiconductor solar cell 10, thereby improving a crystal system of the light-absorbing layer 130. Accordingly, the compound semiconductor solar cell 10 can have improved photovoltaic efficiency characteristics. Alternatively, the substrate 100 may be a ceramics substrate (e.g., of alumina (Al₂O₃) or quartz), a metal substrate (e.g., of stainless steel, Cu tape, Cr steel, an alloy made of nickel (Ni) and iron (Fe) (e.g., Kovar), titanium (Ti), ferritic steel, molybdenum (Mo)) or a flexible polymer film (e.g., of Kapton, polyester, or polyimide film (for example, Upilex or ETH-PI).

The back electrode 110 may be formed of a metal. In order to prevent the back electrode 110 from being delaminated from the substrate 100, the back electrode 110 may be formed of a material having a thermal expansion coefficient close to that of the substrate 100. The back electrode 110 may be formed of, for example, molybdenum. The molybdenum may have high electrical conductivity, characteristics of forming ohmic contacts with other thin films, and high temperature stability under selenium (Se) atmosphere.

The hole-injection layer 120 may be configured in such a way that a difference between valence bands of the hole-injection layer 120 and a p-type semiconductor of the light-absorbing layer 130 is greater than a difference between a conduction band of the hole-injection layer 120 and the valence band of a p-type semiconductor of the light-absorbing layer 130. The hole-injection layer 120 may be formed to have a single-layered structure and, for example, include a metal-containing layer of nickel oxide, vanadium oxide, tungsten oxide, or ruthenium oxide. In other embodiments, the hole-injection layer 120 may be formed to have a multi-layered structure including at least two layers selected from the group consisting of a nickel oxide layer, a vanadium oxide layer, a tungsten oxide layer, or a ruthenium oxide layer. The hole-injection layer 120 may have a thickness ranging from about 0.001 μm to about 1.0 μm.

The light-absorbing layer 130 may be formed of I-III-VI₂ compound semiconductor. The I-III-VI₂ compound semiconductor may be, for example, a chalcopyrite compound semiconductor, such as CuInSe₂, Cu(In, Ga)Se₂, Cu(Al, In)Se₂, Cu(Al, Ga)Se₂, Cu(In,Ga)(S,Se)₂, (Au,Ag,Cu)(In,Ga,Al)(S,Se)₂. The compound semiconductors may be commonly referred as CIGS-based thin films. In example embodiments, the light-absorbing layer 130 may be formed of CuInGaSe₂ having an energy bandgap of about 1.2 eV. In this case, the compound semiconductor solar cell may have the maximum efficiency that is similar to that of a polysilicon solar cell. The light-absorbing layer 130 may be formed to have a thickness of about 2.0-3.0 μm.

The buffer layer 140 may be formed of a material, whose energy bandgap is between those of the light-absorbing layer 130 and the front transparent electrode 150. For example, the buffer layer 140 may be formed of a cadmium sulfide (CdS) film. The buffer layer 140 may have a thickness of about 500 Å and an energy bandgap of about 2.46 eV. The buffer layer 140 may be an n-type semiconductor and be doped with indium (In), gallium (Ga), or aluminum (Al) to have low resistance.

The front transparent electrode 150 may be provided on a front side of the solar cell 10, thereby serving as a window. In this sense, the front transparent electrode 150 may be formed of a material having high optical transmittance and high electrical conductivity. For example, the front transparent electrode 150 may be formed of zinc oxide having an energy bandgap of about 3.3 eV and optical transmittance of about 80% or more. The zinc oxide layer may be doped with aluminum (Al) or boron (B), and in this case, it may have low resistance of about 1×10⁻⁴ Ωcm or less. In the case where the zinc oxide layer is doped with boron (B), the optical transmittance thereof can be increased in a near infrared range, such that a short-circuit current can be increased.

Alternatively, the front transparent electrode 150 may further include an indium-tin-oxide (ITO) film, which has excellent electro-optical characteristics, on the Zinc oxide layer. The front transparent electrode 150 may be provided in the form of a layered structure including an undoped i-type Zinc oxide layer and an n-type Zinc oxide layer having a low resistance provided thereon. The front transparent electrode 150 is an n-type semiconductor, thereby forming a pn-junction in conjunction with the light-absorbing layer 130 that is a p-type semiconductor.

The anti-reflecting layer 160 may be additionally provided on a portion of the front transparent electrode 150. The presence of the anti-reflecting layer 160 may contribute to reduce a reflection loss of sunlight incident to the solar cell 10, and consequently, to improve efficiency of the solar cell 10. The anti-reflecting layer 160 may be formed of, for example, MgF₂.

The grid electrode 170 may be provided at a side of the anti-reflecting layer 160 to be in contact with the front transparent electrode 150. An electric current generated from the solar cell 10 may be collected by the grid electrode 170. The grid electrode 170 may be formed of a metal layer (e.g., of aluminum or nickel/aluminum). Since sunlight cannot pass through the grid electrode 170, it is necessary to minimize an occupying area of the grid electrode 170.

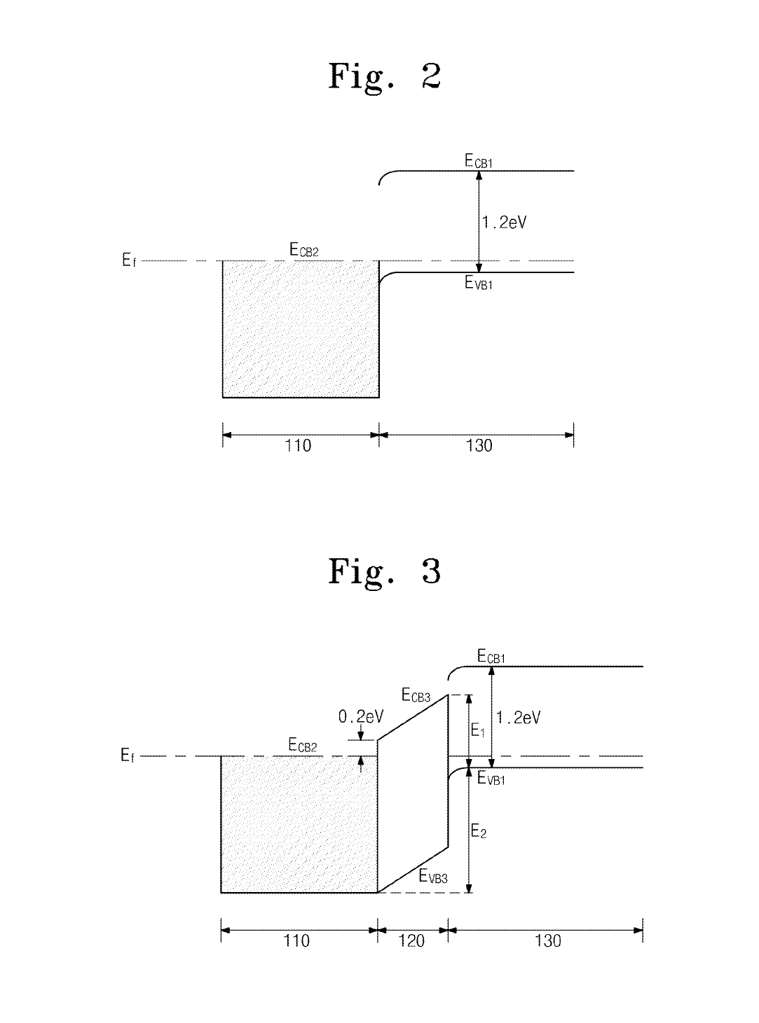

FIG. 2 is an energy band diagram of a back electrode of a conventional solar cell.

According to the conventional solar cell, the hole-injection layer 120 is not provided between the back electrode 110 and the light-absorbing layer 130. In this case, as shown in the energy band diagram of FIG. 2, a valence band E_{VB1} of the light-absorbing layer 130 is formed close to the Fermi level E_{f} and its energy bandgap, i.e., a difference in energy level between conduction and valence bands, E_{CB1}-E_{VB1}, is about 1.2 eV. The conduction band E_{CB2} of the back electrode 110 is formed at the same level as the Fermi level E_{f}. Accordingly, holes can be moved from the light-absorbing layer 130 to the back electrode 110.

FIG. 3 is an energy band diagram of a back electrode of a solar cell according to example embodiments of the inventive concept.

According to example embodiments of the inventive concept, the hole-injection layer 120 is provided between the back electrode 110 and the light-absorbing layer 130. In this case, as shown in the energy band diagram of FIG. 3, the light-absorbing layer 130 has a valence band E_{VB1} close to Fermi level E_{f} and its energy bandgap, i.e., E_{CB1}-E_{VB1}, is about 1.2 eV. The conduction band E_{CB2} of the back electrode 110 is formed at the same level as the Fermi level E_{f}. The hole-injection layer 120 has an energy bandgap of about 3.0 eV, and a difference between its conduction band E_{CB2} and Fermi level E_{f} is 0.2 eV.

Here, a difference E₂ between a valence band E_{VB3} of the hole-injection layer 120 and the valence band E_{VB1} of the p-type semiconductor of the light-absorbing layer 130 may be greater than a difference E₁ between a conduction band E_{CB3} of the hole-injection layer 120 and the valence band E_{VB1} of the p-type semiconductor of the light-absorbing layer 130.

In general, holes generated in the pn junction between the light-absorbing layer 130 and the front transparent electrode 150 should be transferred through the valence band E_{VB3} of the hole-injection layer 120, but holes may be transferred through the conduction band E_{CB3} of the hole-injection layer 120, not the valence band E_{VB3}. In other words, the holes may be directly transferred from the valence band E_{VB1} of the light-absorbing layer 130 to the conduction band E_{CB3} of the hole-injection layer 120. Accordingly, compared with the structure of FIG. 2, the structure of FIG. 3 can provide a technical advantage in terms of holes transfer from the light-absorbing layer 130 to the back electrode 110. As a result, according to example embodiments of the inventive concept, it is possible to realize a transfer of holes generated by the sunlight with ease and consequently to improve the photovoltaic efficiency of the solar cell 10.

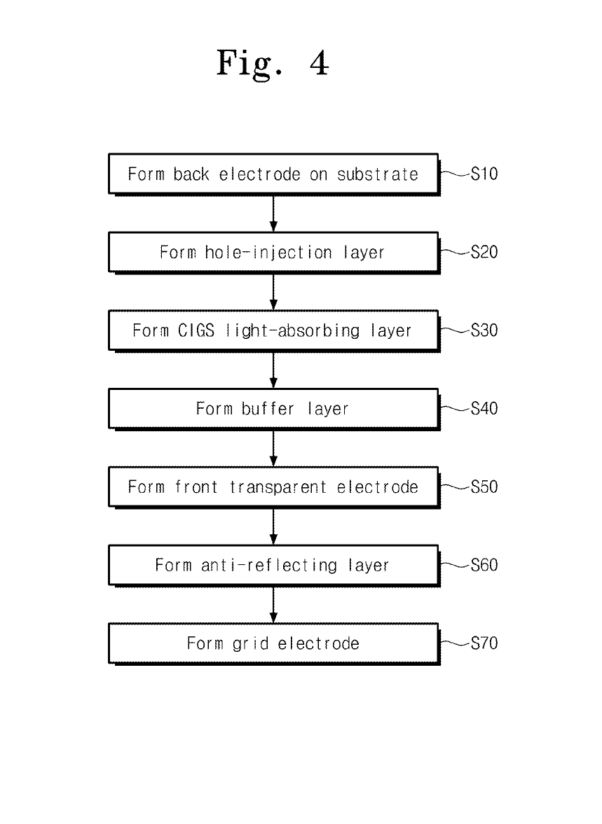

FIG. 4 is a flow chart illustrating a method of fabricating a compound semiconductor solar cell, according to example embodiments of the inventive concept.

Referring to FIGS. 1 and 4, in operation S10, a back electrode 110 is formed on a substrate 100. The substrate 100 may be formed of any one of a sodalime glass substrate, a ceramic substrate such as alumina (Al₂O₃), metal substrates such as stainless steel and a copper tape, etc., or a poly film. In example embodiments, the substrate 100 may be formed of sodalime glass.

The back electrode 110 may be formed of a material having low resistivity. In addition, to prevent the back electrode 110 from being delaminated from the substrate 100, the back electrode 110 may be formed of a material having a thermal expansion coefficient close to that of the substrate 100. For example, the back electrode 110 may be formed of molybdenum (Mo). The molybdenum may have high electrical conductivity, characteristics of forming ohmic contacts with other thin films, and high temperature stability under selenium (Se) atmosphere. The back electrode 110 may be formed by a sputtering method, for example, a direct current (DC) sputtering method.

In operation S20, a hole-injection layer 120 may be formed on the back electrode 110. The hole-injection layer 120 satisfies characteristics in which a difference between the valence band of the hole-injection layer 120 and the valence band of the p-type semiconductor light-absorbing layer 130 is larger than a difference between the conduction band of the hole-injection layer 120 and the valence band of the p-type semiconductor light-absorbing layer 130.

The hole-injection layer 120 may be formed to have a thickness of about 0.001 μm to about 1.0 μm for the performance improvement of the compound semiconductor solar cell 10.

The hole-injection layer 120 may be formed using a sputtering process. For example, in the sputtering process, ionized inert gas (e.g., argon) may be accelerated by an electric field and collide a metal target. Then, metal atoms may be emitted from the metal target and be combined with oxygen or oxygen-containing material (e.g., O₃, O₂, CO₂ or H₂O), which may be supplied during the sputtering process.

The hole-injection layer 120 may be formed to have a single-layered structure and, for example, include one of a nickel oxide layer, a vanadium oxide layer, a tungsten oxide layer, or a ruthenium oxide layer. In other embodiments, the hole-injection layer 120 may be formed to have a multi-layered structure including at least two layers selected from the group consisting of a nickel oxide layer, a vanadium oxide layer, a tungsten oxide layer, or a ruthenium oxide layer.

In operation S30, a light-absorbing layer 130 is formed on the hole-injection layer 120. The light-absorbing layer 130 may be formed of I-III-VI₂ group compound semiconductors. The I-III-VI₂ group compound semiconductors may include chalcopyrite compound semiconductors, for example, CuInSe₂, Cu(In,Ga)Se₂, Cu(Al,In)Se₂, Cu(Al,Ga)Se₂, Cu(In,Ga)(S,Se)₂, (Au,Ag,Cu)(In,Ga,Al)(S,Se)₂, etc. These compound semiconductors may be commonly referred as CIGS-based thin films.

The light-absorbing layer 130 may be formed by a physical or chemical process. The physical process may be, for example, an evaporation method or a mixed method of a sputtering and a selenization process. The chemical process may be, for example, an electroplating method.

The light-absorbing layer 130 may be formed by a co-evaporation method, in which metal elements, such as copper (Cu), indium (In), gallium (Ga), and selenium (Se), is used as a precursor.

Alternatively, the light-absorbing layer 130 may be formed by synthesizing nano-sized particles (e.g., powders, colloids, etc.), mixing the nano-sized particles with a solvent to generate a mixture, printing the mixture on the hole-injection layer 120 in a screen printing method, and reactively sintering the printed mixture.

In operation S40, a buffer layer 140 may be additionally formed on the light-absorbing layer 130. The buffer layer 140 may be formed of a material capable of reducing a difference in energy bandgap between the light-absorbing layer 130 and the front transparent electrode 150. The buffer layer 140 may have a bandgap energy between those of the light-absorbing layer 130 and the front transparent electrode 150.

For example, the buffer layer 140 may be formed of a cadmium sulfide (CdS) film. The CdS film may be formed by a chemical bath deposition (CBD) method. The CdS film may be formed to a thickness of about 500 Å.

The CdS thin film has a bandgap energy of about 2.46 eV, and this corresponds to a wavelength of about 550 nm. The CdS thin film is an n-type semiconductor, and may be doped with indium (In), gallium (Ga) and aluminum (Al) or the like to obtain a low resistance value.

In operation S50, a front transparent electrode 150 is formed on the buffer layer 140. The front transparent electrode 150 may be formed of a material that has a high optical transmittance and good electrical conductivity.

For example, the front transparent electrode 150 may be formed of a zinc oxide (ZnO) film. The ZnO film has a bandgap energy of about 3.3 eV, and may have a high optical transmittance of about 80% or more. Here, the ZnO film may be formed by a radio frequency (RF) sputtering method using a ZnO target, a reactive sputtering method using a Zn target or a metal organic chemical vapor deposition method, etc. The ZnO film may be formed by doping with aluminum (Al) or boron (B) and the like to obtain a low resistance value.

Alternatively, the front transparent electrode 150 may be formed by stacking an ITO thin film having excellent electro-optical characteristics on the ZnO film. Also, the front transparent electrode 150 may be formed by stacking an n-type ZnO film having a low resistance on an undoped i-type ZnO film. The front transparent electrode 150 may be formed by a typical sputtering method. The front transparent electrode 150 is an n-type semiconductor such that a pn-junction is formed with the light-absorbing layer 130 which is a p-type semiconductor.

In operation S60, an anti-reflecting layer 160 may be additionally formed on a portion of the front transparent electrode 150. The anti-reflecting layer 160 may reduce a reflective loss of solar light incident on the solar cell 10. The efficiency of the solar cell 10 may be improved by the anti-reflecting layer 160. For example, the anti-reflecting layer 160 may be formed of magnesium fluoride (MgF₂) film. The MgF₂ film may be formed by an E-beam evaporation method.

In operation S70, a grid electrode 170 may be formed at one side of the anti-reflecting layer 160 and on the front transparent electrode 150. The grid electrode 170 is for collecting currents on a surface of the solar cell 10. The grid electrode 170 may be formed of metals such as aluminum (Al) or nickel (Ni)/aluminum (Al), etc. The grid electrode 170 may be formed by a sputtering method. Since solar light does not incident on a portion occupied by the grid electrode 170, it is necessary to minimize the portion.

According to example embodiments of the inventive concept, a compound semiconductor solar cell may include a hole-injection layer provided between a back electrode and a light-absorbing layer, and thus, holes can be easily transmitted from the light-absorbing layer to the hole-injection layer. Accordingly, the compound semiconductor solar cell can have improved optical efficiency.

While example embodiments of the inventive concepts have been particularly shown and described, it will be understood by one of ordinary skill in the art that variations in form and detail may be made therein without departing from the spirit and scope of the attached claims.

What is claimed is:

1. A compound semiconductor solar cell, comprising:
a back electrode disposed on a substrate;
a hole-injection layer disposed on the back electrode;
a light-absorbing layer disposed on the hole-injection layer; and
a front transparent electrode disposed on the light-absorbing layer,
wherein the hole-injection layer is formed of a metal oxide layer containing one or more metallic element.

2. The solar cell of claim 1, wherein a difference between a valence band of the hole-injection layer and a valence band of a p-type semiconductor of the light-absorbing layer is larger than a difference between a conduction band of the hole-injection layer and the valence band of the p-type semiconductor of the light-absorbing layer.

3. The solar cell of claim 1, wherein the hole-injection layer comprises at least one of a nickel oxide layer, a vanadium oxide layer, a tungsten oxide layer, or a ruthenium oxide layer.

4. The solar cell of claim 1, wherein the hole-injection layer has a multi-layered structure comprising at least two of a nickel oxide layer, a vanadium oxide layer, a tungsten oxide layer, and a ruthenium oxide layer.

5. The solar cell of claim 1, wherein the hole-injection layer has a thickness ranging from 0.001 μm to 1.0 μm.

6. The solar cell of claim 1, wherein the light-absorbing layer is formed of I-III-VI₂ compound semiconductor.

7. The solar cell of claim 1, further comprising a buffer layer interposed between the light-absorbing layer and the front transparent electrode.

8. The solar cell of claim 1, further comprising:
an anti-reflecting layer disposed on the front transparent electrode; and
a grid electrode disposed at a side of the anti-reflecting layer to be in contact with the front transparent electrode.
